(19) United States
(12) Patent Application Publication
(10) Pub. No.: US 2015/0130497 A1
(43) Pub. Date: May 14, 2015

(54) Electrical Test Socket

(71) Applicant: ISC Co., Ltd., Seongnam-si (KR)

(72) Inventor: Gi Min KIM, Gwangju-si (KR)

(21) Appl. No.: 14/537,101

(22) Filed: Nov. 10, 2014

(30) Foreign Application Priority Data
Nov. 12, 2013 (KR) 10-2013-0137121

(51) Int. Cl. G01R 1/04

(52) U.S. Cl. CPC G01R 1/0466
USPC 324/756.02

(57) ABSTRACT

Provided is an electrical test socket that is arranged between a terminal of a test target device and a pad of test equipment in order to electrically connect the terminal and the pad, the electrical test socket including: a socket body including a central hole at a center thereof in order to house the test target device inside; a pin connection member comprising a plurality of conductive pins that are arranged on locations corresponding to the terminal of the test target device housed in the central hole of the socket body, and whose upper end contacts the terminal of the test target device, and a housing having penetration holes into which the conductive pins are inserted to support the conductive pins; and a sheet-type connection member in which a plurality of conductive parts are arranged on locations corresponding to the conductive pins, wherein the plurality of conductive parts are arranged on a bottom portion of the pin connection member, exhibit conductivity only in a thickness direction, and are elastically deformed in the thickness direction, wherein the conductive pins have a rectangular pillar shape.

### RELATED APPLICATION

This application claims the benefit of Korean Patent Application No. 10-2013-0137121, filed on Nov. 12, 2013 in the Korean Intellectual Property Office, the disclosure of which is incorporated herein in its entirety by reference.

### BACKGROUND

1. Field

One or more embodiments of the present invention relate to an electrical test socket, and more particularly, to an electrical test socket of improving electrical characteristics by maximizing an area where the electrical test socket contacts a contacting object.

2. Description of the Related Art

Semiconductor devices manufactured through a complicated procedure have various electrical tests to examine characteristics and existence of defects. In electrical tests for semiconductor devices, for example, semiconductor integrated circuit devices such as package integrated circuits (IC) and multi-chip modules (MCMs), and wafers in which ICs are formed, an electrical test socket is arranged between a semiconductor device to be tested and test equipment in order to electrically connect a terminal formed on a side portion of the semiconductor device, and a pad of the test equipment.

A related art with regard to test sockets is disclosed in Korean patent registration No. 640626. The test socket 100 according to the related art includes a housing 110 having a plurality of first penetration holes 130, and a guide portion 112 that is connected to an inside of the housing 110, and has second penetration holes 135 to which the first penetration holes 130 are extended. Pogo pins 120 are housed in the first and second penetration holes 130 and 135, and electrically connect a semiconductor device 300 and a test board 200.

The first penetration holes 130 housing a metal plunger 125 are respectively disposed around the semiconductor device 300, and are formed of a small caliber portion 131 having a first diameter, and a large caliber portion 133 that is disposed near a rubber connection pin 129 and having a diameter that is larger than the first diameter. A step 132 may be formed between the small caliber portion 131 and the large caliber portion 133. The metal plunger 125 may stop moving because a stopper 123 is stopped by the step 132.

Therefore, the stopper 123 and the step 132 may prevent the pogo pins 120 from being separated from the test socket 100 to the outside. Each of the second penetration holes 135 may have the same/smaller diameter as/than the large caliber portion 133, and may have a diameter that may house the rubber connection pin 129 by being connected to the rubber connection pin 129. Accordingly, the diameter of the rubber connection pin 129 may be the same as or smaller than that of the large caliber portion 133 of each of the first penetration hole 130. The test socket 100 is mounted on the test board 200 in order to examine the electrical characteristics of the semiconductor device 300. After electrode terminals of the test board 200 are connected to the rubber connection pin 129 of the test socket 100, a top surface of the semiconductor device 300 is pressurized. The pogo pins 120 move in an upper direction until the pogo pins 120 is stopped by the step 132 due to the elasticity of the rubber connection pin 129. Protrusions 121 of the metal plunger 125 contact solder balls 302 of the semiconductor device 300. As pressure keeps being applied, the rubber connection pin 129, the electrode terminals 202, protrusions 121, and the solder balls 302 may closely contact each other due to the applied pressure. When the test socket 100 closely contacts the test board 200 and the semiconductor device 300, the electrical characteristics may be tested.

The test socket according to the related art has the following problems.

According to types of the terminals and those of external leads, the semiconductor device may be classified into a dual in-line (DIP) type, a quad in-line (QID) type, a flat package (FPT) type, a pin grid array (PGA) type, a leadless chip carrier (LCC) type, a ball grid array (BGA) type, or the like, and the pogo pins that contact the terminals of the semiconductor device may have a cylindrical shape.

The pogo pins 120 having a cylindrical shape have no problems when the pogo pins 120 are contact the BGA type terminals such as the solder balls having a ball shape as illustrated in FIG. 1. However, as illustrated in FIGS. 2A and 2B, when the pogo pins 120 contact the flat FTP type terminals, shapes of the flat FTP terminals and the pogo pins 120 are different, and thus an area where the flat FTP terminals and the pogo pins 120 electrically contact each other may not be secured enough. That is, as illustrated in FIGS. 2A and 2B, when the pogo pins 120 contact terminals having a rectangular shape, the pogo pins 120 having a cylindrical cross-section do not entirely contact, but partially contact the surface of the terminals of the semiconductor device, thereby causing poor electrical contacts. As a result, reliability of entire tests may be disadvantageously applied.

### SUMMARY

The present invention is provided to solve the above-described problems, and one or more embodiments of the present invention include an electrical test socket of improving electrical characteristics by maximizing an electrical contact area.

Additional aspects will be set forth in part in the description which follows and, in part, will be apparent from the description, or may be learned by practice of the presented embodiments.

According to one or more embodiments of the present invention, there is provided an electrical test socket that is arranged between a terminal of a test target device and a pad of test equipment in order to electrically connect the terminal and the pad, the electrical test socket including: a socket body including a central hole at a center thereof in order to house the test target device inside; a pin connection member including a plurality of conductive pins that are arranged on locations corresponding to the terminal of the test target device housed in the central hole of the socket body, and whose upper end contacts the terminal of the test target device, and a housing having penetration holes into which the conductive pins are inserted to support the conductive pins; and a sheet-type connection member in which a plurality of conductive parts are arranged on locations corresponding to the conductive pins, wherein the plurality of conductive parts are arranged on a bottom portion of the pin connection member, exhibit conductivity only in a thickness direction, and are elastically deformed in the thickness direction, wherein the conductive pins have a rectangular pillar shape.

Bumps may be formed on an end portion of each of the conductive pins.

The conductive pins may include the end portion on which the bumps are formed, and a pin body that is extended to one direction from the end portion, wherein the pin body may have protrusions that are protruded in a direction perpendicular to the one direction.

The penetration holes of the housing may have a square shape or a circular shape.

The housing may be detachably combined with the socket body.

The housing may have a structure in which plates including rectangular holes are stacked.

Each of the plurality of plates may be formed of insulation synthetic resin, and may be separable from each other.

The sheet-type connection member may be detachably combined with the socket body.

According to one or more embodiments of the present invention, there is provided an electrical test socket that is arranged between a terminal of a test target device and a pad of test equipment in order to electrically connect the terminal and the pad, the electrical test socket including: a plurality of conductive pins which is arranged at locations corresponding to the terminal of the test target device, and of which top surfaces contact the terminal of the test target device; and a housing having penetration holes into which the conductive pins are inserted to support each of the conductive pins, wherein the conductive pins have a shape like a polyprism.

The conductive pins may have a rectangular pillar shape.

The housing may have a structure in which a plurality of plates are vertically stacked, and each of the plurality of plates may have a polygonal hole, wherein the polygonal holes may be gathered to form the penetration holes.

The electrical test socket may further include a socket body supporting the test target device, and having the penetration holes formed on the locations corresponding to the terminal of the test target device, wherein the conductive pins may contact the terminal of the test target device through the penetration holes.

### BRIEF DESCRIPTION OF THE DRAWINGS

These and/or other aspects will become apparent and more readily appreciated from the following description of the embodiments, taken in conjunction with the accompanying drawings in which:

FIG. 1 is a view illustrating an electrical test socket, according to the related art;

FIGS. 2A and 2B are schematic side and bottom views illustrating an example conducting an electrical test by using the electrical test socket of FIG. 1;

FIG. 3 is an exploded perspective view of an electrical test socket, according to an embodiment of the present invention;

FIG. 4 is a perspective view illustrating a combination of the electrical test socket of FIG. 3;

FIG. 5 is a bottom view of FIG. 4;

FIG. 6 is a cross-sectional view, taken along a line VI-VI of FIG. 4;

FIG. 7 is a perspective view illustrating cross-sections of major portions in FIG. 3;

FIG. 8 is a perspective view of a conductive pin that is one element of the electrical test socket of FIG. 3;

FIGS. 9A through 9H are schematic cross-sectional views illustrating a method of manufacturing the conductive pin of FIG. 8;

FIGS. 10A through 10C are a variety of embodiments of the conductive pin of FIG. 8; and

FIG. 11 is a perspective view illustrating some portions of an electrical test socket, according to another embodiment of the present invention.

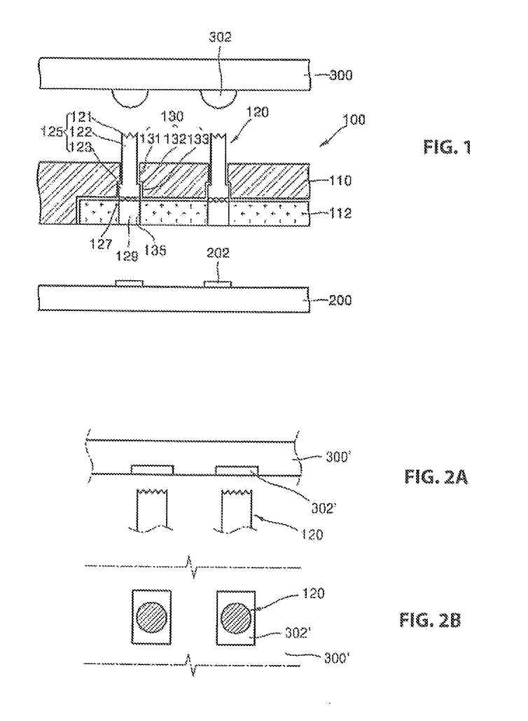

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

Hereinafter, an electrical test socket 10 according one or more an embodiment of the present invention will be described in detail with reference to the attached drawings.

The electrical test socket 10 according to an embodiment of the present invention is applied to various types of semiconductor devices respectively having a Dual In-line (DIP) type terminal, a Quad In-line (QIT) type terminal, a flat package (FPT) type terminal, a pin grid array (PGA) type terminal, a leadless chip carrier (LCC) type terminal, or a ball grid array (BGA) type terminal, and is used to examine electrical characteristics of the semiconductor devices by connecting each semiconductor device and test equipment.

The electrical test socket 10 may include a socket body 20, a pin connection member 30, and a sheet-type connection member 40.

The socket body 20 has a central hole 21 at the center of the socket body 20 in order to house a test target device inside, which is a semiconductor device necessary to be examined, and the central hole 21 has a square shapes. The socket body 20 has a square shape having a predetermined height, the center of which has the central hole 21 having the square shape. A structure and a shape of the socket body 20 are similar with the related art, thereby omitting the detailed descriptions.

The pin connection member 30 is combined with the socket body 20, and electrically connects a terminal of the test target device and a pad of the test equipment arranged inside the socket body 20 in an indirect way or a direct way. The pin connection member 30 may include conductive pins 31, and a housing 32.

The conductive pins 31 are arranged on locations corresponding to the terminal of the test target device, and have a rectangular pillar shape. The conductive pins 31 may be formed of nickel alloy that has high electrical conductivity and is solid. That is, the conductive pins 31 may be formed of nickel-cobalt, but are not limited thereto. Also, surfaces of the conductive pins 31 may be plated with precious metals such as gold, silver, or the like having high conductivity.

Each of the conductive pins 31 may include an end portion 31a that has bumps and contacts the terminal of the test target device, and a pin body 31b that is extended from the end portion 31a to one direction. The end portion 31a of each of the conductive pins 31 may have triangular bumps, and thus, may surely contact the terminal of the test target device.

The pin body 31b has the rectangular pillar shape, and both sides of the pin body 31b have a pair of protrusions 31c perpendicular to the one direction. The pin body 31b is inserted into the housing 32, and remains fixed into the housing 32 due to the protrusions 31c.

The housing 32 has penetration holes 322 into which the conductive pins 31 are inserted in order to support each of the conductive pins 31. The penetration holes 322 are formed in the locations corresponding to the terminal of the test target device. The penetration holes 322 should have a shape corresponding to the conductive pins 31, and particularly, the shape may be square. However, the shape of the penetration holes 322 is not limited thereto, and the shape may be circular. The housing 32 has a rectangular shape, and it is good to have enough space to house the conductive pins 31 inside. The housing 32 may be detachably combined with the socket body 20. In particular, it is good for the housing 32 to be detachably combined with a bottom of the socket body 20.

The housing 32 may be formed of an insulating material, and may have a structure in which plates 321, which may be separated from each other, are stacked. That is, the housing 32 may have a structure in which the plates 321 whose thickness is thin are vertically stacked. When rectangular holes 321a formed in each of the plates 321 form the penetration holes 322 when each of the plates 321 are stacked.

Each of the plates 321 may be bonded, but is not limited thereto. Also, edges of the plates 321 may be coupled by bolts or pins.

The sheet-type connection member 40 is arranged between the pin connection member 30 and the test equipment so as to connect the pin connection member 30 and the pad of the test equipment, and the conductivity is exhibited only in a thickness direction. The sheet-type connection member 40 includes an anisotropic sheet 41 and a frame 42, and the anisotropic sheet 41 includes conductive parts 411, and an insulating part 412.

The conductive parts 411 are arranged at a bottom of the pin connection member 30, and exhibit the conductivity in the thickness direction. Elasticity may be changed in the thickness direction, and there are the plurality of conductive parts 411. Each of the conductive parts 411 may be disposed at a location corresponding to each of the conductive pins 31. The conductive parts 411 are arranged at locations corresponding to the terminal of the test target device, and conductive particles that exist in an elastic material are arranged in parallel in the thickness direction.

Heat-resistant polymer materials having a bridge structure are appropriate to be used as the elastic material forming the conductive parts 411. A variety of materials may be used as a curable material of forming the polymer materials that may be used to obtain the bridge-structure polymer material, but a liquid silicone rubber may be the most appropriate material. The liquid silicone rubber may be an addition type or a condensed type, but the addition type may be better. In a case where the conductive parts 411 are formed of the curable material having the liquid silicone rubber (hereinafter, referred to as ‘silicone rubber curable material’), compression set distortion of the silicone curable material should be less than or equal to 10% at 150° C., but the lower the compression set distortion is, the better the silicon curable material is. That is, at most 6% of the compression set distortion is better than at most 8% of the compression set distortion. In a case where the compression set distortion is equal to or more than 10%, and an obtainable elastic conductive sheet is repeatedly used under a high-temperature environment, a chain reaction of the conductive particles in the conductive parts 411 may not be perfectly performed, and thus the conductivity may not be maintained.

It may be appropriate for the conductive particles to be formed after highly conductive metal is sheathed in surfaces of core particles having a magnetic property. Materials forming the magnetic core particles may include iron, nickel, cobalt, or copper or resin that is coated with iron, nickel, or cobalt. Saturation magnetization thereof should be at least 0.1 Wb/m² or higher, preferably 0.3 Wb/m² or higher, or more preferably 0.5 Wb/m² or higher, and in particular, the material may be iron, nickel, cobalt, or alloys thereof.

Gold, silver, rhodium, platinum, chromium, etc. may be used as the highly conductive metals coated on the surfaces of the magnetic core particles, and from among the above-mentioned metals, gold is appropriate since gold is chemically stable and has high conductivity.

The insulating part 412 performs a function that supports the conductive parts 411 and maintains an insulating property between the conductive parts 411. The insulating part 412 may have, but may not be limited thereto, the same elastic material as in the conductive parts 411, and any material having high elasticity and conductivity may be used.

At a center of the frame 42, a hole through which the anisotropic sheet 41 is combined is formed, and thus the frame 42 supports the anisotropic sheet 41. The frame 42 may be formed of a metal material or a plastic material, and may be detachably combined since the frame 42 is arranged at a bottom of the socket body 20. A conventional coupling method such as bolts may be used in order to couple the frame 42 at the bottom of the socket body 20.

A method for manufacturing the conductive pins 31 will be briefly described.

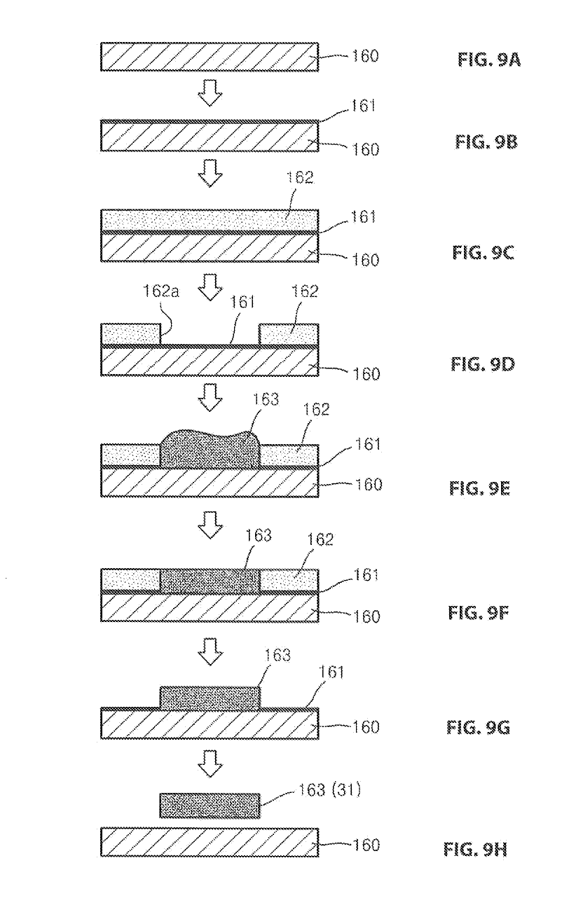

As illustrated in FIG. 9A, a substrate 160 formed of a silicone material is prepared, and a conductive layer 161 is formed on a top surface of the substrate 160 as illustrated in FIG. 9B. Then, as illustrated in FIG. 9C, a dry film 162 is arranged on the conductive layer 161, and a predetermined groove 162a is formed in the dry film 162 as illustrated in FIG. 9D. The groove 162a may have a form corresponding to a form of the conductive pins 31 to be manufactured. As illustrated in FIG. 9E, the groove 162a formed in the dry film 162 may be filled with a plating material in order to form a plating layer 163, and planarization is performed as illustrated in FIG. 9F. The dry film 162 formed on the substrate 160 is removed as illustrated in FIG. 9G, and lastly the entire manufacturing method is completed when the conductive pins 31 that are manufactured are removed from the substrate 160.

The electrical test socket 10 according to the embodiment of the present invention may have the following effects.

While the socket body 20 is combined with the pin connection member 30 and the sheet-type connection member 40, and the electrical test socket 10 is mounted on the test equipment, the test target device may be connected to the pin connection member 30 through the central hole 21 of the socket body 20. In this case, the terminal of the test target device may contact upper parts of the conductive pins 31. When predetermined electrical signals are applied from the test equipment, the electrical signals are transmitted to the terminal of the test target device after passing the conductive parts 411 of the sheet-type connection member 40, and conductive pins 31. As a result, a predetermined electrical test is conducted. The electrical test socket 10 according to the embodiment of the present invention may have an area of contacting the terminal of the test target device higher than that of existing cylindrical conductive pins since the conductive pins 31, and the terminal of the test target device have the rectangular pillar shape.

As the area of contacting the terminal of the test target device increases, an electrical connection ability is improved, and thus the reliability of the test may be secured.

Also, since both the conductive pins 31 and penetration holes of the pin connection member 30 have the square shape, rotation of the conductive pins 31 in the penetration holes may be prevented. For example, according to the related art, the conductive pins and the penetration holes have the cylindrical form so that the conductive pins may be rotated when the conductive pins move in a vertical direction in the penetration holes. That is, the conductive pins may be rotated based on a central axis. In addition, a predetermined gap between the conductive pins and the penetration holes exists in general, the conductive pins may not be surely connected to the terminal of the test target device when the conductive pins are rotated by moving in a horizontal direction (due to the gap). However, according to the present invention, since both conductive pins 31 and penetration holes have the square shape, the rotation may be prevented although the conductive pins 31 and the penetration holes move in the horizontal direction due to the gap, and thus the conductive pins 31 and the penetration holes may surely contact at an exact location.

According to an embodiment of the present invention, the housing 32 has the structure in which a plurality of plates are stacked, and thus the penetration holes may be precisely manufactured as designed. Also, although a portion of the housing 32 is damaged, only the portion may be replaced so that maintenance costs may be reduced.

The electrical test socket 10 according to the present embodiment may be changed as follows.

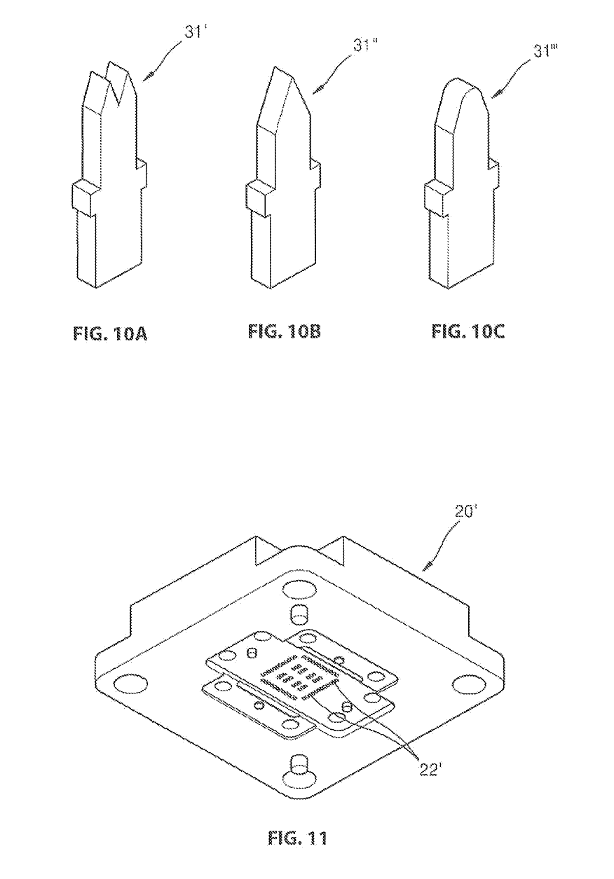

According to the above-described embodiments, the conductive pins 31 in the electrical test socket 10 may have three bumps at top and bottom surfaces of the conductive pins 31, but are not limited thereto. As illustrated in FIG. 10, the conductive pins 31 may have various forms. For example, as illustrated in FIG. 10A, two bumps may be formed on top surfaces of conductive pins 31′, and as illustrated in FIG. 10B, a single bump may be formed on top surfaces of conductive pins 31″. Also, as illustrated in 10C, a single bump whose end is rather rounded may be formed on top surfaces of conductive pins 31″. The bumps may be formed on bottom surfaces of the conductive pins, and accordingly, the coupling with the anisotropic sheet 41 may be firm.

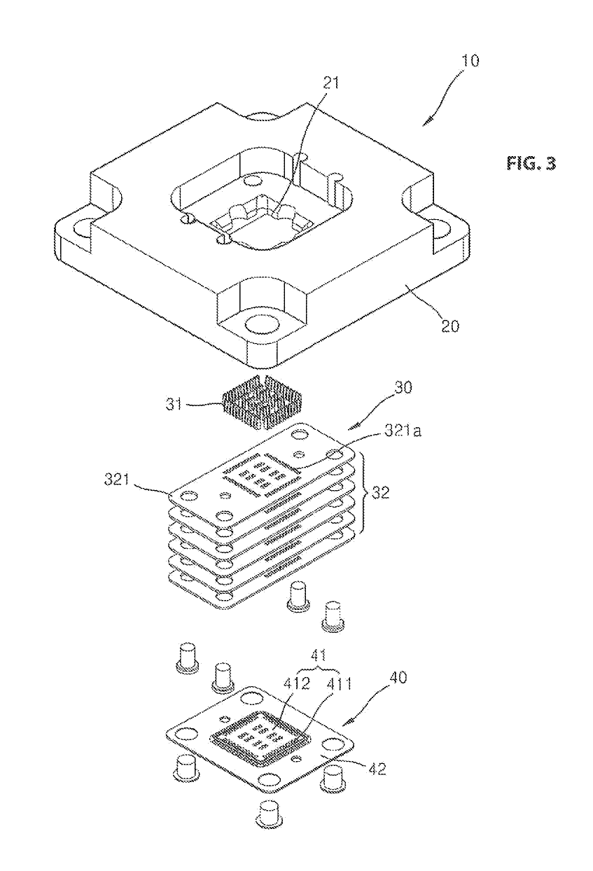

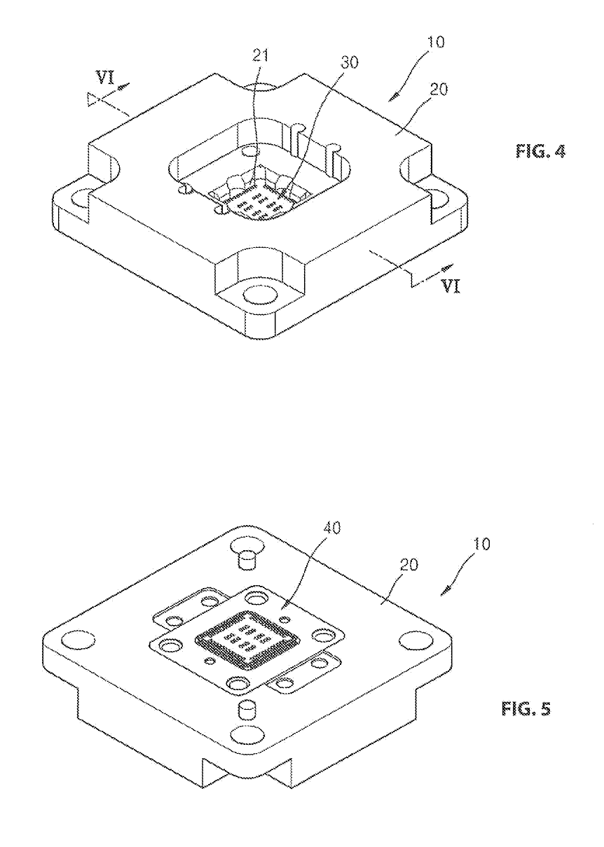

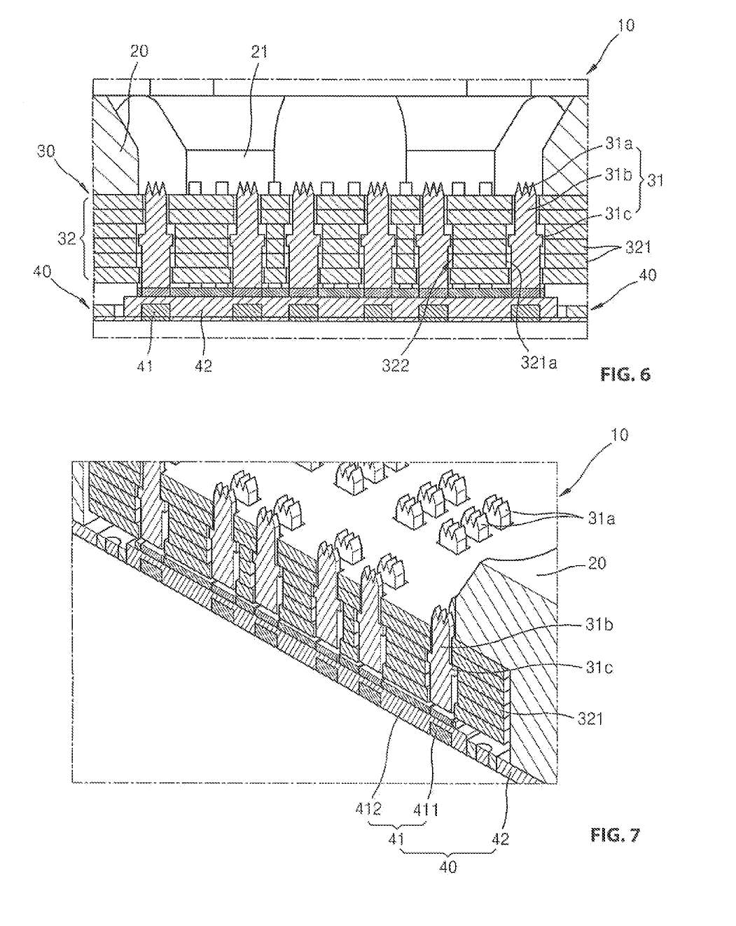

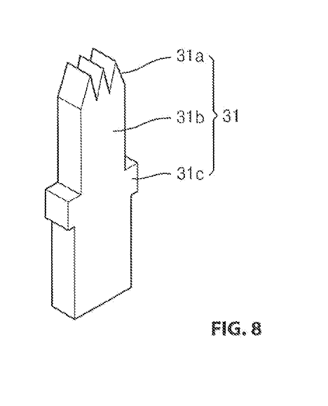

Also, as illustrated in FIGS. 11 and 12, a socket body 20′ in which a plurality of penetration holes 22′ are formed in the locations corresponding to the terminal of the test target device or the conductive pins of the pin connection member 30 may be used, and structures of other components may be the same as the components illustrated in FIG. 3.

According to the above embodiment, the housing 32 is formed of a number of plates, but is not limited thereto. The housing 32 may be formed as a single body, or may have various forms.

As described above, according to the one or more of the above embodiments of the present invention, in the electrical test socket 10, the conductive pins 31 of the pin connection member 30 have the rectangular pillar shape, and thus the contact area of the conductive pins 31 may be maximized when the conductive pins 31 contact the square terminal or the square pad. Therefore, the electrical characteristics may be improved so that the reliability of the electrical test may be secured.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims.

What is claimed is:

1. An electrical test socket that is arranged between a terminal of a test target device and a pad of test equipment in order to electrically connect the terminal and the pad, the electrical test socket comprising:
a socket body comprising a central hole at a center thereof in order to house the test target device inside;
a pin connection member comprising a plurality of conductive pins that are arranged on locations corresponding to the terminal of the test target device housed in the central hole of the socket body, and whose upper end contacts the terminal of the test target device, and a housing having penetration holes into which the conductive pins are inserted to support the conductive pins; and
a sheet-type connection member in which a plurality of conductive parts are arranged on locations corresponding to the conductive pins, wherein the plurality of conductive parts are arranged on a bottom portion of the pin connection member, exhibit conductivity only in a thickness direction, and are elastically deformed in the thickness direction,
wherein the conductive pins have a rectangular pillar shape.

2. The electrical test socket of claim 1, wherein bumps are formed on an end portion of each of the conductive pins.

3. The electrical test socket of claim 2, wherein the conductive pins comprise the end portion on which the bumps are formed, and a pin body that is extended to one direction from the end portion, wherein the pin body has protrusions that are protruded in a direction perpendicular to the one direction.

4. The electrical test socket of claim 1, wherein the penetration holes of the housing have a square shape or a circular shape.

5. The electrical test socket of claim 1, wherein the housing is detachably combined with the socket body.

6. The electrical test socket of claim 1, wherein the housing has a structure in which a plurality of plates comprising rectangular holes are stacked.

7. The electrical test socket of claim 6, wherein each of the plurality of plates is formed of insulation synthetic resin, and is separable from each other.

8. The electrical test socket of claim 1, wherein the sheet-type connection member is detachably combined with the socket body.

9. An electrical test socket that is arranged between a terminal of a test target device and a pad of test equipment in order to electrically connect the terminal and the pad, the electrical test socket comprising:
a plurality of conductive pins which is arranged at locations corresponding to the terminal of the test target device, and of which top surfaces contact the terminal of the test target device; and
a housing having penetration holes into which the conductive pins are inserted to support each of the conductive pins,
wherein the conductive pins have a shape like a polyprism.

10. The electrical test socket of claim 9, wherein the conductive pins have a rectangular pillar shape.

11. The electrical test socket of claim 9, wherein the housing has a structure in which a plurality of plates are vertically stacked, and each of the plurality of plates has a polygonal hole,
wherein the polygonal holes are gathered to form the penetration holes.

12. The electrical test socket of claim 11, further comprising a socket body supporting the test target device, and having the penetration holes formed on the locations corresponding to the terminal of the test target device,
wherein the conductive pins contact the terminal of the test target device through the penetration holes.
